(19) United States
(12) Patent Application Publication
(10) Pub. No.: US 2026/0247909 A1
(43) Pub. Date: Aug. 20, 2026

(54) Substrate Processing Apparatus, Method of Detecting Tilt of Substrate Retainer, Substrate Processing Method, Method of Manufacturing Semiconductor Device and Non-transitory Computer-readable Recording Medium

(71) Applicant: Kokusai Electric Corp., Toyama-shi (JP)

(72) Inventors: Yukinori ABURATANI, Toyama-shi (JP); Seiya KITO, Toyama-shi (JP); Takayuki OTA, Toyama-shi (JP)

(73) Assignee: Kokusai Electric Corp., Toyama-shi (JP)

(21) Appl. No.: 19/415,930

(22) Filed: Dec. 11, 2025

(30) Foreign Application Priority Data
Feb. 20, 2025 (JP) 2025-025647

(51) Int. Cl. H10P 72/00; H10P 72/76

(52) U.S. Cl. CPC H10P 72/0606; H10P 72/0431; H10P 72/0464; H10P 72/7624

(57) ABSTRACT

It is possible to detect a tilt of a substrate retainer by a technique that includes: a rotator rotatably supporting a substrate retainer provided with support columns; a sensor attached to a transfer robot for transferring a substrate to the substrate retainer such that a distance between the sensor and the substrate retainer and a relative height of the sensor with respect to the substrate retainer are variable, and configured to detect the support columns within an optical path; and a controller capable of: (a) causing the rotator to rotate the substrate retainer such that the support columns intersect with the optical path; (b) calculating center positions of the substrate retainer from detection results of the sensor at a plurality of heights; and (c) determining whether a tilt of the substrate retainer is within a reference degree based on a difference in the center positions in a height direction.

### CROSS-REFERENCE TO RELATED PATENT APPLICATION

This non-provisional U.S. patent application is based on and claims priority under 35 U.S.C. § 119 of Japanese Patent Application No. 2025-025647, filed on Feb. 20, 2025, in the Japanese Patent Office, the entire contents of which are hereby incorporated by reference.

### BACKGROUND

### 1. Field

The present disclosure relates to a substrate processing apparatus, a method of detecting a tilt of a substrate retainer, a substrate processing method, a method of manufacturing a semiconductor device and a non-transitory computer-readable recording medium.

### 2. Related Art

According to some related arts, in a substrate processing performed as a part of a manufacturing process of a semiconductor device, for example, a batch type (vertical type) substrate processing apparatus may be used to collectively (or simultaneously) process a plurality of substrates such as semiconductor silicon wafers. In such a vertical type substrate processing apparatus, a substrate retainer (also referred to as a “boat”), which is configured to support (or hold) the plurality of substrates while the substrates are horizontally oriented with their centers aligned with one another in a multistage manner, may be used. In addition, the boat may be provided with a plurality of support structures (support columns) configured to support the substrates.

In such a vertical type substrate processing apparatus, it is preferable to perform a maintenance work periodically. To perform the maintenance work, the boat may be removed from the vertical type substrate processing apparatus. In such a case, when the boat is reattached, a misalignment (that is, a positional deviation) of the boat may occur.

### SUMMARY

According to the present disclosure, there is provided a technique capable of detecting a tilt of a substrate retainer.

According to an embodiment of the present disclosure, there is provided a technique that includes: a rotator configured to rotatably support a substrate retainer provided with a plurality of support columns; a sensor attached to a transfer robot configured to transfer a substrate to the substrate retainer such that a distance between the sensor and the substrate retainer and a relative height of the sensor with respect to the substrate retainer are variable, and configured to be capable of detecting the plurality of support columns within an optical path thereof; and a controller configured to be capable of: (a) causing the rotator to rotate the substrate retainer such that the plurality of support columns intersect with the optical path; (b) calculating center positions of the substrate retainer from detection results of the sensor at a plurality of heights; and (c) determining whether a tilt of the substrate retainer is within a reference degree based on a difference in the center positions in a height direction.

### BRIEF DESCRIPTION OF THE DRAWINGS

FIG. 1 is a diagram schematically illustrating a perspective view of a substrate processing apparatus according to one or more embodiments of the present disclosure.

FIG. 2 is a diagram schematically illustrating a perspective view of a transfer robot according to the embodiments of the present disclosure.

FIG. 3 is a block diagram schematically illustrating a configuration of a controller and its related components of the substrate processing apparatus according to the embodiments of the present disclosure.

FIG. 4 is a flow chart schematically illustrating a tilt detection process according to the embodiments of the present disclosure.

FIG. 5 is a diagram schematically illustrating a plan view for explaining the tilt detection process according to the embodiments of the present disclosure.

FIGS. 6A and 6C are diagrams schematically illustrating states at a timing when a support column starts crossing a laser beam in the tilt detection process according to the embodiments of the present disclosure, and FIGS. 6B and 6D are diagrams schematically illustrating states at a timing when the support column finishes crossing the laser beam.

FIG. 7 is a flow chart schematically illustrating a tilt detection process according to a modified example of the embodiments of the present disclosure.

FIG. 8 is a diagram schematically illustrating a contact between an optical axis and the support column in the tilt detection process according to the embodiments of the present disclosure.

### DETAILED DESCRIPTION

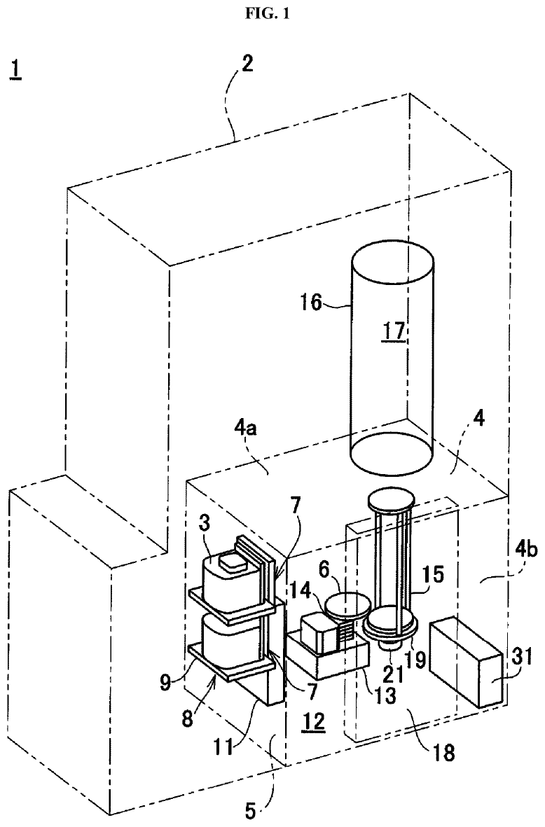

Hereinafter, one or more embodiments (also simply referred to as “embodiments”) according to the technique of the present disclosure will be described with reference to FIGS. 1 to 3. In addition, the drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match. For example, the number of each component described in the present specification is not limited to one, and the number of each component may be two or more unless otherwise specified in the present specification. In addition, the same or similar reference numerals represent the same or similar components in the drawings, and redundant descriptions related thereto will be omitted.

### Outline of Substrate Processing Apparatus

A substrate processing apparatus described in the present embodiments is used in a manufacturing process of a semiconductor device. The substrate processing apparatus is configured to perform a processing (for example, a heat treatment process) on a substrate to be processed by heating the substrate by using a heater while the substrate is accommodated in a process chamber. More specifically, as the substrate processing apparatus, a vertical type substrate processing apparatus (which is configured to simultaneously process a plurality of substrates stacked in a vertical direction at a predetermined interval therebetween) may be used.

As the substrate to be processed by the substrate processing apparatus, for example, a semiconductor wafer substrate (hereinafter, also simply referred to as a “wafer cassette” or a “wafer”) on which the semiconductor device is manufactured may be used. In addition, as the heat treatment process performed by the substrate processing apparatus, for example, a process such as an oxidation process, a diffusion process, an annealing process, a reflow process, a sintering process, a film forming process by using a thermal CVD (Chemical Vapor Deposition) reaction and a film quality improving process (film quality treatment process) may be performed.

### (1) Configuration of Substrate Processing Apparatus

An overall configuration of the substrate processing apparatus will be described with reference to FIG. 1. FIG. 1 is a diagram schematically illustrating main components of the substrate processing apparatus.

A substrate processing apparatus 1 includes a housing 2. A pod 3 (which is configured as a sealed type substrate container) may be transferred (loaded) into the substrate processing apparatus 1 by an in-process transfer apparatus (not shown) and may be transferred (unloaded) out of the substrate processing apparatus 1 by the in-process transfer apparatus.

A sub-housing 4 is provided at a lower rear portion of the housing 2 in a front-rear direction to extend toward a rear end of the substrate processing apparatus 1. A pair of wafer loading/unloading ports 7 through which a wafer 6 is loaded into or unloaded out of the sub-housing 4 is provided at a front wall 5 of the sub-housing 4 in two stages in a vertical direction. That is, as the wafer loading/unloading ports 7, an upper wafer loading/unloading port and a lower loading/unloading port are provided. Pod openers 8 are provided for the wafer loading/unloading ports 7, respectively. Hereinafter, each of the wafer loading/unloading ports 7 may also be referred to as a “wafer loading/unloading port 7”, and each of the pod openers 8 may also be referred to as a “pod opener 8”.

The pod opener 8 may include: a mounting table (placement table) 9 where the pod 3 is placed thereon; and an opening/closing structure 11 capable of opening (or detaching) and closing (or attaching) a lid of the pod 3. The pod opener 8 is configured such that a wafer entrance of the pod 3 is opened or closed by opening or closing the lid of the pod 3 placed on the mounting table 9 by using the opening/closing structure 11.

The sub-housing 4 (which is also referred to as a “loading chamber” or a “loading area”) defines a transfer chamber 12 (which is airtight from a space in which the pod opener 8 is located). A transfer robot (which is a transfer apparatus or a transfer structure) 13 is provided at a front region of the transfer chamber 12. That is, the transfer robot 13 may also be referred to as a “transfer structure” 13. The transfer robot 13 is provided with a predetermined number of wafer mounting plates (which is also referred to as “wafer placement plates” or “wafer grippers”) 14 capable of supporting (or holding) a predetermined number of wafers. That is, among a plurality of wafers including the wafer 6, the predetermined number of wafers can be placed on the wafer mounting plates 14. Hereinafter, each of the wafer mounting plates 14 may also be referred to as a “wafer mounting plate 14”, and the plurality of wafers including the wafer 6 may also be referred to as “wafers 6”. The wafer mounting plate 14 is configured to be capable of being moved linearly in a horizontal direction, capable of being rotated in the horizontal direction and capable of being elevated or lowered in the vertical direction. The transfer robot 13 is configured such that the wafer 6 can be loaded into or unloaded out of a boat 15 serving as a substrate retainer provided in the transfer chamber 12. The wafer mounting plates 14 may also be referred to as “hands”, “end effectors”, “chucks”, “forks”, or “tweezers”, and may be constituted by, for example, five mounting plates.

A process furnace 16 such as a vertical type process furnace is provided adjacent to and above the transfer chamber 12. The process furnace 16 defines a process chamber 17 therein. A lower end of a furnace opening below the process chamber 17 is open, and is configured to be opened or closed by using a furnace opening shutter (not shown). In the process chamber 17, the heat treatment process is performed on the wafer 6 accommodated in the boat 15.

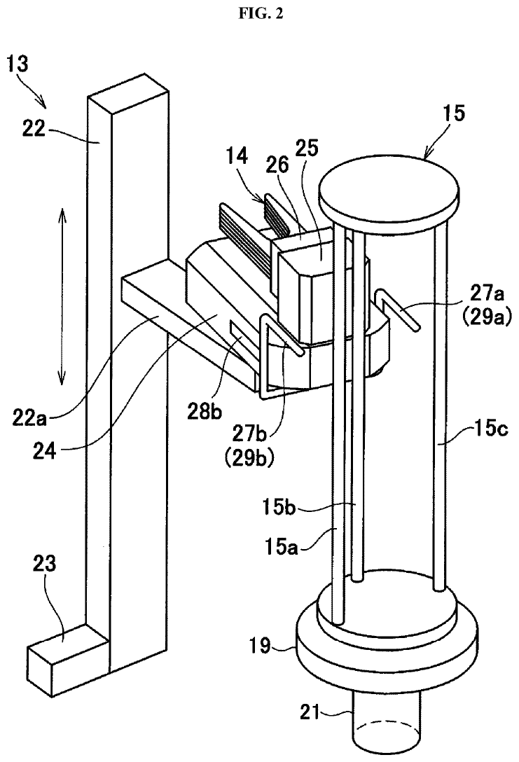

A boat elevator 18 configured to elevate and lower the boat 15 is provided on a side surface of the sub-housing 4. A seal cap 19 serving as a lid is attached horizontally to an arm (not shown) connected to an elevating platform of the boat elevator 18. The seal cap 19 is configured to support the boat 15 vertically, and is configured to be capable of airtightly closing the furnace opening when the boat 15 is loaded into the process furnace 16. The transfer chamber 12 is provided adjacent to the process chamber 17. The boat 15 is accommodated in the transfer chamber 12 or the process chamber 17. In the transfer chamber 12, the wafer 6 is loaded into or unloaded out of the boat 15. The boat 15 is configured to support (or hold) the plurality of wafers 6 (for example, from 50 wafers to 175 wafers) while the wafers 6 are horizontally oriented with their centers aligned with one another in a multistage manner. As shown in FIG. 2, the boat 15 is provided with support columns 15a, 15b and 15c serving as columns configured to support the wafers 6. The support columns 15a, 15b and 15c are arranged in parallel with an axis of symmetry (center) of the boat 15 and at a predetermined circumferential interval therebetween, for example, at a 90° interval. The support columns 15a, 15b and 15c are provided with grooves (slots) configured to support the wafers 6. Lower surfaces of the grooves serve as substrate supporting surfaces on which the wafers 6 can be placed and supported. In addition, each of the support columns 15a, 15b and 15c is formed in a shape that is plane-symmetrical with respect to a plane defined with the axis of symmetry of the boat 15 and including a central axis of each of the support columns 15a, 15b and 15c. In addition, for example, as shown in FIG. 2, the support columns 15a, 15b and 15c are arranged such that the support columns 15a and 15c are plane-symmetrical with respect to a plane passing through the axis of symmetry of the boat 15 and the central axis of the support column 15b.

A rotator (which is a rotating structure) 21 is provided at the seal cap 19 to be opposite to the process chamber 17. The rotator 21 is configured to support (that is, rotatably support) the boat 15 such that the boat 15 can be rotated around a central axis corresponding to the center of the wafer 6. A rotating shaft of the rotator 21 passes through the seal cap 19, and is connected to the boat 15. The rotator 21 serves as a rotation driver (which is a rotation driving structure) configured to rotate the boat 15. That is, the rotator 21 is configured to rotate the wafers 6 by rotating the boat 15 within the process chamber 17.

A clean air supplier (which is a clean air supply structure) (not shown) is disposed at a location adjacent to a first side surface 4a of the sub-housing 4 to be opposite to the boat elevator 18 (that is, opposite to a second side surface 4b of the sub-housing 4). For example, the clean air supplier is constituted by a supply fan and a dust filter to supply clean air (which is purified air or an inert gas). On the first side surface 4a of the sub-housing 4 (that is, a first side surface of the transfer chamber 12), an outlet for the clean air is provided. A notch aligner (which is a notch alignment structure) (not shown) may be installed between the transfer robot 13 and the clean air supplier. The notch aligner serves as a substrate aligner (which is a substrate alignment structure) configured to align a circumferential position of the wafer 6.

The clean air is ejected through the clean air supplier. Then, after circulating through the notch aligner, the transfer robot 13 and the boat 15, a part of the clean air is sucked in by a local exhaust duct (or a common exhaust duct) installed on a second side surface of the transfer chamber 12 and exhausted to an outside (outer portion) of the housing 2 through an exhaust duct. The second side surface 4b of the sub-housing 4 (that is, the second side surface of the transfer chamber 12) is provided with an exhaust port. Another part of the clean air is ejected again into the transfer chamber 12 through the clean air supplier.

An exemplary configuration of the transfer robot 13 will be described with reference to FIG. 2. FIG. 2 is a diagram schematically illustrating a state in which the transfer robot 13 transfers the wafer 6 to the boat 15. That is, the wafer mounting plates (end effectors) 14 of the transfer robot 13 face the support columns 15a and 15c of the boat 15.

The transfer robot 13 may include: a guide 22 arranged along an up-down direction (Z-axis direction); a Z-axis direction driver (which is a Z-axis direction driving structure) 23; a Y-axis rotation driver (which is a Y-axis rotation driving structure) 24; an X-axis direction driver (which is an X-axis direction driving structure) 25; and a V-axis direction driver (which is a V-axis direction driving structure) 26. Each driver 23 to 26 may also be referred to as a “drive system”.

The Z-axis direction driver 23 is provided at a lower end or an upper end of the guide 22 to move a mount 22a in the up-down direction (Z-axis direction, vertical direction) along the guide 22.

The Y-axis rotation driver 24 is provided on an upper surface (top surface) of the mount 22a such that the Y-axis rotation driver 24 itself can rotate in a Y-axis direction. Thereby, the Y-axis rotation driver 24 can rotate the X-axis direction driver 25 in a clockwise direction or a counterclockwise direction horizontally (that is, rotate the X-axis direction driver 25 around the Y-axis) while supporting the X-axis direction driver 25 such that an X-axis and the Y-axis of the X-axis direction driver 25 are perpendicular to each other. Since the pod 3 is usually located between a direction of the boat 15 and an opposite direction thereof when viewed from the Y-axis, it is sufficient that a rotation range of the Y-axis rotation driver 24 is approximately 180°.

The X-axis direction driver 25 is provided integrally with the Y-axis rotation driver 24 or provided within the Y-axis rotation driver 24 to move the V-axis direction driver 26 forward and backward in the horizontal direction (X-axis direction) while supporting the V-axis direction driver 26. In addition, a “forward” direction of the X-axis is defined as a direction in which the wafer mounting plate 14 is moved so as to protrude from the Y-axis rotation driver 24 to enter the boat 15 or the pod 3.

The V-axis direction driver 26 is provided at the X-axis direction driver 25 and is configured to support the five wafer mounting plates 14 horizontally while adjusting an interval (spacing) thereof in the Z-axis direction.

Thereby, the transfer robot 13 can pick up the wafers 6 from the pod 3 by using the wafer mounting plates 14 and can transfer (charge or load) the wafers 6 into the boat 15. Then, after an appropriate process is performed on the wafers 6 in the process furnace 16, the transfer robot 13 can pick up (discharge or unload) the wafers 6 from the boat 15 by using the wafer mounting plates 14 and can transfer (charge or load) the wafers 6 into the pod 3. An outer shape of the Y-axis rotation driver 24 is set such that a rotation radius of the Y-axis rotation driver 24 is equal to or slightly greater than a minimum rotation radius around the Y-axis of the wafer mounting plate 14 and the V-axis direction driver 26. For example, a length of the Y-axis rotation driver 24 in the X-axis direction is set to be equal to or slightly greater than a combined length of the wafer mounting plate 14 and the V-axis direction driver 26, side surfaces parallel to the X-axis are provided on side portions of the Y-axis rotation driver 24.

The transfer robot 13 is further provided with: sensor rods 27a and 27b serving as arms provided on both sides of the Y-axis rotation driver 24; and forward/backward drivers (which are forward/backward driving structure) 28a and 28b serving as sensor drivers configured to move the sensor rods 27a and 27b in the X-axis direction. In FIG. 2, among the forward/backward drivers 28a and 28b, the forward/backward driver 28b alone is shown.

The sensor rods 27a and 27b are configured to extend upward along both sides of the Y-axis rotation driver 24 to approximately (substantially) the same height as one of the wafer mounting plates 14. The sensor rods 27a and 27b are configured to bend at approximately a right angle in a direction opposite to an attachment direction of the wafer mounting plate 14 to the X-axis direction driver 25, that is, in a direction toward a rear of the X-axis. The sensor rods 27a and 27b are configured to support (hold) fiber sensors 29a and 29b serving as sensors.

On front ends (tips) of the sensor rods 27a and 27b, light transmitting/receiving structures of the fiber sensors 29a and 29b are provided, respectively. For example, the fiber sensors 29a and 29b are configured as a pair of transmission-type sensors such that one of the fiber sensors 29a and 29b transmits a laser beam 39 and the other of the fiber sensors 29a and 29b receives the laser beam. The fiber sensors 29a and 29b can be located such that an optical path (optical axis) formed between the light transmitting/receiving structures is parallel to a tangent to the wafer 6, that is, approximately perpendicular to a longitudinal direction of the boat 15. The fiber sensors 29a and 29b may be configured as mapping sensors configured to perform a mapping operation. For example, by detecting an interruption (blocking) in the optical path, the mapping sensors are configured to be capable of counting the number of the wafers 6 loaded in the pod 3 or in the boat 15, or configured to be capable of detecting normal or abnormal conditions such as a protrusion of the wafer 6 and a misalignment (or positional deviation) of the boat 15. When the sensor rods 27a and 27b advance, the optical axis remains aligned, and is horizontal. The sensor rods 27a and 27b may be connected through the Y-axis rotation driver 24 such that the sensor rods 27a and 27b move together with each other. In such a case, only one of the forward/backward drivers 28a and 28b may be provided. In addition, the optical path (that is, the optical axis of the laser beam) between the fiber sensors 29a and 29b is perpendicular or substantially perpendicular to the rotating shaft of the rotator 21, that is, a rotation axis of the boat 15, and is also perpendicular or substantially perpendicular to an extension direction of each of the support columns 15a to 15c.

In addition, the forward/backward drivers 28a and 28b are arranged on both sides of the Y-axis rotation driver 24, and are configured to support the sensor rods 27a and 27b, respectively, such that the sensor rods 27a and 27b can move in the X-axis direction between protruded positions and storage positions. In other words, the wafer mounting plates 14 and the sensor rods 27a and 27b are arranged back-to-back with respect to the Y-axis rotation driver 24, and can be moved independently on the X-axis. The sensor rods 27a and 27b can be moved along the longitudinal direction (up-down direction, Z direction) of the support columns 15a to 15c of the boat 15 by using the Z-axis direction driver 23.

Thereby, the transfer robot 13 is configured to be capable of mapping the wafers 6 in the pod 3 by using the fiber sensors 29a and 29b. The transfer robot 13 is further configured to be capable of mapping the wafers 6 in the boat 15 by using the fiber sensors 29a and 29b, or configured to be capable of detecting the positional deviation in the X-axis direction and the Y-axis direction between a reference position and a current position of the boat 15 by the fiber sensors 29a and 29b. In the present embodiments, the term “reference position” of the boat 15 refers to a position where the boat 15 is installed vertically while the center of the boat 15 coincides with a center of rotation of the boat 15 (rotator 21). That is, the reference position may be defined as a position reached by extending a center of the rotating shaft (mechanical center) of the rotator 21 with the boat 15 unloaded in the Z-axis direction in a coordinate system (mechanical coordinates) of the transfer robot 13. The reference position may also include a height (height position information) of each wafer slot (not shown) configured to support the wafer 6 in such a time.

As shown in FIG. 2, the sensor rods 27a and 27b of the transfer robot 13 are moved by using the Y-axis rotation driver 24 toward and away from the boat 15, that is, in a direction in which the X-axis faces the center of the boat 15. In such a time, the forward/backward drivers 28a and 28b drive the sensor rods 27a and 27b (fiber sensors 29a and 29b) such that the sensor rods 27a and 27b can be located with a predetermined positioning accuracy at either one of two positions, that is, advanced positions near a center position of the boat 15 and retracted positions away from the center position of the boat 15. In addition, when the boat 15 is rotated by using the rotator 21, one of the support columns 15a to 15c of the boat 15 is located so as to block the laser beam emitted from one of the fiber sensors 29a and 29b. In FIG. 2, the support column 15b is located closest to the Y-axis of the transfer robot 13, that is, on the X-axis.

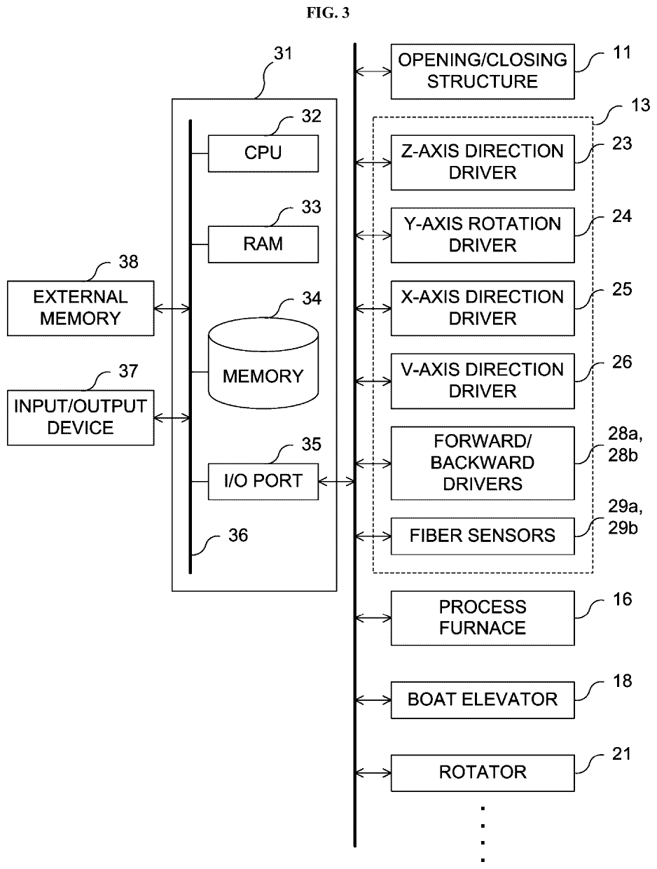

In addition, a controller 31 serving as a control structure (control apparatus, control system) is provided at an appropriate position in the housing 2, for example, in a corner of the sub-housing 4 in FIG. 1. As shown in FIG. 3, the controller 31 is constituted by a computer including a CPU (Central Processing Unit) 32, a RAM (Random Access Memory) 33, a memory 34 and an I/O port (input/output port) 35. The RAM 33, the memory 34 and the I/O port 35 are configured to be capable of exchanging data with the CPU 32 through an internal bus 36. For example, an input/output device 37 (which is constituted by components such as a touch panel) is connected to the controller 31. In addition, an external memory 38 can also be connected to the controller 31.

For example, the memory 34 is configured by a component such as a flash memory, a hard disk drive (HDD) and a solid state drive (SSD). For example, a control program configured to control an operation of the substrate processing apparatus 1 and a process recipe containing information on procedures and conditions of a substrate processing described later may be readably stored in the memory 34. The process recipe is obtained by combining steps (procedures) of the substrate processing described later such that the controller 31 can execute the steps by the substrate processing apparatus 1 to acquire a predetermined result, and functions as a program. Hereinafter, the process recipe and the control program may be collectively or individually referred to as a “program”. Thus, in the present specification, the term “program” may refer to the recipe alone, may refer to the control program alone or may refer to both of the recipe and the control program. The RAM 33 functions as a memory area (work area) where a program or data read by the CPU 32 is temporarily stored.

The I/O port 35 is connected to the components described above such as the opening/closing structure 11, the transfer robot 13, the process furnace 16, the boat elevator 18 and the rotator 21.

The CPU 32 is configured to read the control program from the memory 34 and execute the control program read from the memory 34. In addition, the CPU 32 is configured to read the recipe from the memory 34, for example, in accordance with an operation command inputted from the input/output device 37. In accordance with contents of the process recipe read from the memory 34, the CPU 32 may be configured to be capable of controlling various operations such as an operation of opening and closing the lid of the pod 3, an operation of transferring the wafer 6 by the transfer robot 13, an operation of supplying a process gas into the process furnace 16 and exhausting the process gas from the process furnace 16, an operation of adjusting a flow rate of the process gas, an operation of controlling a pressure (inner pressure) of the process chamber 17, an operation of adjusting a temperature (inner temperature) of the process chamber 17, an operation of elevating and lowering the boat 15 by the boat elevator 18, and an operation of adjusting the rotation and a rotation speed of the boat 15 by the rotator 21.

The controller 31 may be embodied by installing the above-described program stored in the external memory 38 into the computer. For example, the external memory 38 may include a magnetic tape, a magnetic disk such as a hard disk drive (HDD), an optical disk such as a CD, a magneto-optical disk such as an MO and a semiconductor memory such as a USB memory and a solid state drive (SSD). The memory 34 or the external memory 38 may be embodied by a non-transitory computer readable recording medium. Hereafter, the memory 34 and the external memory 38 may be collectively or individually referred to as a “recording medium”. Thus, in the present specification, the term “recording medium” may refer to the memory 34 alone, may refer to the external memory 38 alone, or may refer to both of the memory 34 and the external memory 38. Instead of the external memory 38, a communication interface such as the Internet and a dedicated line may be used for providing the program to the computer.

### (2) Teaching Step

When performing a maintenance work on the substrate processing apparatus 1, various structures (components) are removed from the housing 2 and the sub-housing 4, and are subjected to various processes such as a cleaning process and a replacement process. In particular, when reinstalling (or reattaching) the boat 15, the transfer robot 13 loads or unloads the wafer 6 onto or out of the boat 15 based on information on the reference position. That is, in a program for performing a process of transferring the wafer 6, the reference position of the boat 15 is set in advance. Then, wafer transfer position information indicating the center position of the wafer 6 when transferring the wafer 6 to the boat 15 is set based on the reference position. The wafer 6 is then transferred based on the wafer transfer position information. When there is a misalignment (deviation) between an installed position of the boat 15 and the reference position, the wafer 6 or the wafer mounting plate 14 may come into contact with the support columns 15a to 15c of the boat 15. Therefore, a teaching process is performed to correct the wafer transfer position information and obtain new wafer transfer position information such that the wafer 6 and the like do not come into contact with the support columns 15a to 15c.

On the other hand, when the boat 15 is tilted or when a foreign matter is present on a bottom of the boat 15, simply correcting the wafer transfer position information may not be enough to prevent a contact between the wafer 6 and the support columns 15a to 15c. In such a case, the process of transferring the wafer 6 may not be performed.

Therefore, according to the present embodiments, as a pre-processing step prior to a teaching step, the controller 31 automatically detects a tilt (inclination) of the boat 15 after reinstallation and performs a tilt detection process to determine whether the tilt of the boat 15 is within a range in which the wafer 6 can be transferred.

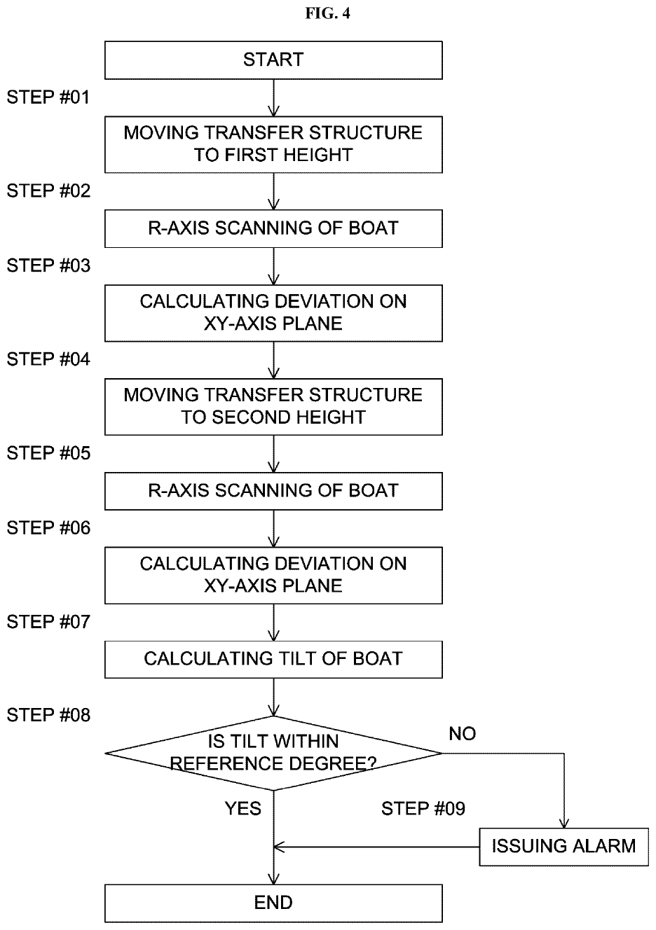

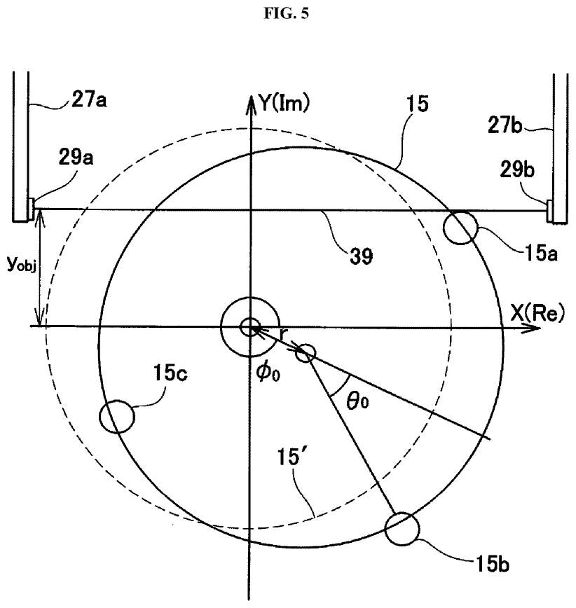

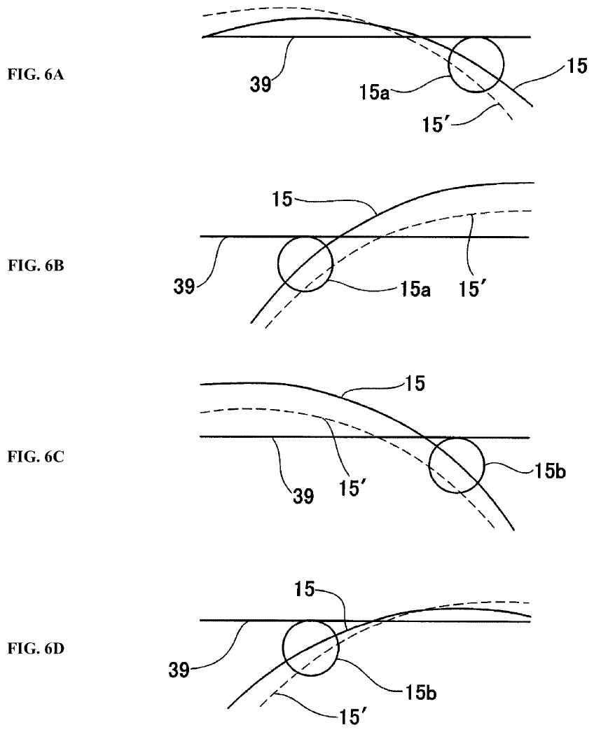

Hereinafter, the tilt detection process according to the present embodiments will be described with reference to a flow chart in FIG. 4 and FIGS. 5 and 6A to 6D. In the following description, processes and operations of components constituting the substrate processing apparatus 1 are controlled by the controller 31 in accordance with a tilt detection program. In FIGS. 5 and 6A to 6D, a dashed line indicates a boat 15′ in the reference position, and a solid line indicates the actual boat 15.

### STEP #01

First, the controller 31 moves the transfer robot 13 to a first height (Z1). In the present embodiments, for example, the first height may refer to a height of a substrate supporting surface of a first slot (lowermost slot) and a height in its vicinity.

### STEP #02

Subsequently, the center position of the boat 15 is obtained at the first height. As shown in FIG. 5, the controller 31 drives the Z-axis direction driver 23, the Y-axis rotation driver 24, the X-axis direction driver 25, the V-axis direction driver 26, and the forward/backward drivers 28a and 28b such that a part of the boat 15 is located between the sensor rods 27a and 27b, that is, such that the sensor rods 27a and 27b are stationary in the advanced positions. That is, the transfer robot 13 is moved such that an optical path of the laser beam 39 emitted from the fiber sensors 29a and 29b is located within a rotation radius of the boat 15 at the reference position, or such that the support columns 15a to 15c cross (or intersect with) an optical axis of the laser beam 39.

With the fiber sensors 29a and 29b in operation, the controller 31 rotates the boat 15 around the rotation axis of the boat 15 (R-axis direction) at a constant speed by using the rotator 21 to perform an R-axis scanning. In addition, when the sensor rods 27a and 27b in the advanced positions mechanically interfere (contact) with one or more of the support columns 15a to 15c, the controller 31 controls the forward/backward drivers 28a and 28b to move the sensor rods 27a and 27b to the retracted positions. Thereby, it is possible to prevent the sensor rods 27a and 27b and the fiber sensors 29a and 29b from being damaged.

When one of the support columns 15a to 15c crosses between the fiber sensors 29a and 29b, for example, from a timing the support column 15a starts crossing the laser beam 39 (see FIG. 6A) until a timing the support column 15a finishes crossing the laser beam 39 (see FIG. 6B), the laser beam 39 is blocked by the support column 15a, and the light transmitting/receiving structures of the fiber sensors 29a and 29b stop receiving the laser beam 39.

The controller 31 detects the rotation speed of the boat 15 in such a time, and further detects a time (timing) from a start to an end of each of the support columns 15a to 15c crossing (passing through) the laser beam 39 and a time (timing) from the end of each of the support columns 15a to 15c crossing the laser beam 39 and a start of a subsequent support column crossing the laser beam 39. Then, the controller 31 stores such values in the memory 34. In addition, since the optical path of the laser beam 39 emitted from the fiber sensors 29a and 29b lies within a plane perpendicular to the rotation axis of the boat 15, it is possible to detect the start and the end of such a crossing with a high accuracy.

### STEP #03

Based on the results of the R-axis scanning performed in the STEP #02, an amount of deviation (hereinafter, also referred to as a “deviation amount”) “r” on an XY-axis plane between the center (center position) of the boat 15 at the first height and the reference position is calculated. In addition, a deviation angle (deviation rotation angle) φ₀ of the center (center position) of the boat 15 relative to a reference angle is calculated. In addition, an angle (direction angle) θ₀ indicating a relationship between a direction of deviation of the center of the boat 15 and an orientation of the boat 15 (for example, a direction of the support column 15b) is calculated. That is, the direction angle θ₀ (which is a second predetermined rotation angle) relative to the reference angle (which is a first predetermined rotation angle) is calculated. Based on the deviation amount r, the deviation angle φ₀ and the direction angle θ₀, the center position of the wafer 6 at the first height is calculated. Hereinafter, a method of calculating the deviation amount r, the deviation angle φ₀ and the direction angle θ₀ at the first height will be described.

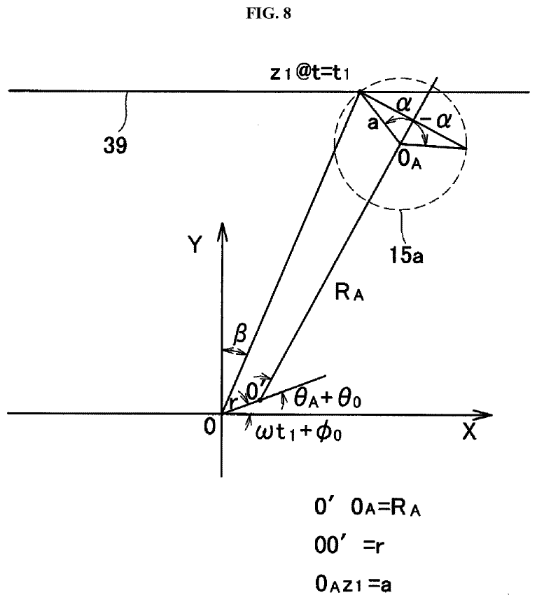

As shown in FIGS. 5 and 8, a horizontal complex plane coordinate system is defined, with an X-axis thereof parallel to the optical path formed between the fiber sensors 29a and 29b. The X axis is set as the reference angle (0°). In such a case, a predetermined point Z(tₙ) on a support column of the boat 15 at a time tₙ can be expressed by [Equation 1].

$$Z ( {t}_{n} ) = {Z}_{0} + {re}^{j ( ω t + ϕ 0 )} + {Re}^{j ( ω t + ϕ 0 + θ x + θ 0 )} + {ae}^{j ( ω t + ϕ 0 + θ x + θ 0 + α )} \qquad [ Equation 1 ]$$

In [Equation 1], Z₀ is the coordinate of the reference position (the rotating shaft of the rotator 21) and can be expressed as X₀+jY₀. In addition, ω represents a rotation frequency of the boat 15, R represents a distance from the center of the boat 15 to a center of the support column (that is, each of the support columns 15a to 15c), and “a” represents a distance from the center of the support column to each of predetermined points (support column radius), all of which are known values. The predetermined points are points where the support column initially and lastly comes into contact with the light beam (laser beam), and in a case of a D-cut support column shown in the present example, the predetermined points correspond to edges at both ends of the D-cut support column. In addition, θₓ represents an arrangement angle of each of the support columns 15a to 15c. For example, when the support column 15b is used as the reference, θ_{B}=0. In such a case, the position of the support column 15a can be expressed as θ_{B}−θ_{A}=94.7 (deg), and the position of the support column 15c can be expressed as θ_{C}−θ_{B} =94.7 (deg). In addition, in FIG. 5, Y_{obj} represents a distance in the Y-axis direction from the reference position to the optical path of the laser beam 39.

As shown in FIGS. 6A to 6D, [Equation 1] is used to calculate the deviation amount r, the deviation angle φ₀ and the direction angle θ₀, as shown below, at four times (timings): a time t₁ when the support column 15a starts crossing the laser beam 39; a time t₂ when the support column 15a finishes crossing the laser beam 39; a time t₃ when the support column 15b starts crossing the laser beam 39; and a time t₄ when the support column 15b finishes crossing the laser beam 39. The following shows equations for calculating the distance (Y_{obj}) in the Y-axis direction from the reference position to the optical path of the laser beam 39 at the times t₁ to t₄.

$${Y}_{obj} = Im [ Z ( {t}_{1} ) ] = {Y}_{0} + r sin ( ω {t}_{1} + {ϕ}_{0} ) + {R}_{A} sin ( ω {t}_{1} + {ϕ}_{0} + {θ}_{A} + {θ}_{0} ) + asin ( ω {t}_{1} + {ϕ}_{0} + {θ}_{A} + {θ}_{0} + \qquad [ Equation 2 ]$$

$${Y}_{obj} = Im [ Z ( {t}_{2} ) ] = {Y}_{0} + r sin ( ω {t}_{2} + {ϕ}_{0} ) + {R}_{A} sin ( ω {t}_{2} + {ϕ}_{0} + {θ}_{A} + {θ}_{0} ) + asin ( ω {t}_{2} + {ϕ}_{0} + {θ}_{A} + {θ}_{0} \qquad [ Equation 3 ]$$

$${Y}_{obj} = Im [ Z ( {t}_{3} ) ] = Im [ {Z}_{0} + ( r + {Re}^{j ( θ B + θ 0 )} ) {e}^{j ( ω t 3 + ϕ 0 )} + ja ] = {Y}_{0} + r sin ( ω {t}_{3} + {ϕ}_{0} ) + {R}_{B} sin ( ω {t}_{3} + {ϕ}_{0} + {θ}_{B} + {θ}_{0} ) + asin ( ω {t}_{3} + {ϕ}_{0} + {θ}_{B} + {θ}_{0} + α ) \qquad [ Equation 4 ]$$

$${Y}_{obj} = Im [ Z ( {t}_{4} ) ] = Im [ {Z}_{0} + ( r + {Re}^{j ( θ B + θ 0 )} ) {e}^{j ( ω t 4 + ϕ 0 )} + ja ] = {Y}_{0} + r sin ( ω {t}_{4} + {ϕ}_{0} ) + {R}_{B} sin ( ω {t}_{4} + {ϕ}_{0} + {θ}_{B} + {θ}_{0} ) + asin ( ω {t}_{4} + {ϕ}_{0} + {θ}_{B} + {θ}_{0} - α ) \qquad [ Equation 5 ]$$

In the equations mentioned above, R_{A} and R_{B} are the distances from the center of the boat 15 to the centers of the support columns 15a and 15c, respectively. By solving the four simultaneous equations for the deviation amount r, the deviation angle φ₀, the direction angle θ₀ and the distance Y_{obj}, it is possible to calculate the deviation on a horizontal plane (in the X-axis direction and the Y-axis direction) between the center of the boat 15 at the first height and the reference position. Because [Equation 2] to [Equation 5] are nonlinear simultaneous equations, the deviation can be obtained by using numerical calculations such as the Newton's method. When there are four or more variables, a set of nonlinear simultaneous equations equal to or greater than the number of the variables is created to calculate the variables. On the contrary, when there are more equations than variables, a solution can be obtained by using the nonlinear least-squares method.

In addition, by using the deviation amount r and the deviation angle φ₀, it is possible to determine how much the center of the boat 15 is deviated from the reference position when the boat 15 is at the reference angle (first predetermined angle). In addition, by using the direction angle θ₀ (second predetermined angle), and it is also possible to determine a direction in which the center of the boat 15 is deviated from the reference position. Therefore, when simply obtaining the deviation amount r, the direction angle θ₀ may not be calculated.

### STEP #04

When values such as the deviation amount r at the first height are calculated, the controller 31 retracts the sensor rods 27a and 27b to the retracted positions and stops the sensor rods 27a and 27b, and then moves the transfer robot 13 to a second height (Z2). In the present embodiments, for example, the second height may refer to a height of a substrate supporting surface of a top slot (uppermost slot) and a height in its vicinity.

STEP #05

At the second height, the controller 31 stops the sensor rods 27a and 27b at the advanced positions and then obtains the center position of the boat 15. The center position of the boat 15 is obtained using the same method as in the STEP #02. Since the sensor rods 27a and 27b are stopped at the advanced positions with the predetermined positioning accuracy, it is possible to suppress measurement errors at different heights.

### STEP #06

After the center position of the boat 15 at the second height is obtained, the controller 31 calculates the deviation amount r on the XY-axis plane between the center of the boat 15 at the second height and the reference position, the deviation angle (deviation rotation angle) φ₀ relative to the reference angle, and the angle (direction angle) θ₀ indicating the relationship between the direction of deviation of the center of the boat 15 and the orientation of the boat 15 (for example, the direction of the support column 15b). The deviation amount r, the deviation angle φ₀, and the direction angle θ₀ are calculated using the same method as in the STEP #03. Based on the deviation amount r, the deviation angle φ₀ and the direction angle θ₀, the center position of the wafer 6 at the second height is calculated.

### STEP #07

The controller 31 calculates the tilt of the boat 15 based on the center position of the wafer 6 at the first height, the center position of the wafer 6 at the second height, and the second height relative to the first height (that is, a distance between the first height and the second height).

### STEP #08

The controller 31 compares the tilt of the boat 15 calculated as described above with a reference degree of the tilt (which is set in advance), and determines whether the tilt of the boat 15 is within the reference degree. In the present embodiments, the reference degree indicates a limit of the tilt at which the wafer 6 and the wafer mounting plate 14 do not come into contact with the support columns 15a to 15c of the boat 15 when the wafer 6 is transferred based on the wafer transfer position information. Therefore, when the tilt of the boat 15 is within the reference degree, it is possible to transfer a component such as the wafer 6 without coming into contact with the support columns 15a to 15c. On the contrary, when the tilt of the boat 15 is greater than the reference degree, the component such as the wafer 6 may come into contact with the support columns 15a to 15c.

When the controller 31 determines that the tilt of the boat 15 calculated in the STEP #07 is within the reference degree, the controller 31 determines that the wafer 6 can be transferred, and terminates the tilt detection process.

### STEP #09

When it is determined, in the STEP #08, that the tilt of the boat 15 is greater than the reference degree, the controller 31 issues an alarm to notify that the tilt of the boat 15 has exceeded the reference degree, and then terminates the tilt detection process. For example, the alarm may be a light or a sound alarm, or the input/output device 37 may display a message indicating that the reference degree has been exceeded.

When the alarm is issued, an operator (worker) reinstalls the boat 15, and then the tilt detection process from the STEP #01 to the STEP #09 is performed again. The tilt detection process is repeatedly performed until the tilt of the boat 15 is within the reference degree.

When the tilt detection process is terminated without issuing the alarm, that is, when the tilt of the boat 15 is within the range in which the wafer 6 can be transferred, the teaching process is executed. The controller 31 calculates an amount of correction for the actual center position of the wafer 6 relative to the center position of the wafer 6 at the reference position, and updates the wafer transfer position information based on the amount of correction.

In addition, the tilt detection process may further include a step of measuring a height from a reference height to the first slot (the lowermost slot) on one of the support columns 15a to 15c to determine whether the foreign matter is present at the bottom of the boat 15. A previously measured height from the reference height to the first slot is compared with an actually measured height from the reference height to the first slot, and when they do not match, it can be determined that the foreign matter is present at the bottom of the boat 15.

In addition, while the center positions of the boat 15 is calculated at two heights (that is, the first height and the second height), according to the present embodiments, the center positions of the boat 15 at three or more heights may be calculated, and the tilt of the boat 15 may be calculated based on a difference between the center positions of the boat 15 in a height direction (vertical direction).

### (3) Substrate Processing

Hereinafter, an overview of the substrate processing of processing the substrate using the substrate processing apparatus 1 will be described. For example, the substrate processing apparatus 1 serves as a semiconductor device manufacturing apparatus, and the substrate processing serves as a part of a manufacturing process of the semiconductor device. The substrate processing is performed after it is determined that the tilt of the boat 15 is within the reference degree by performing the tilt detection process. In the following descriptions, the processes and the operations of the components constituting the substrate processing apparatus 1 are controlled by the controller 31.

### Substrate Loading Step

When the pod 3 is supplied to the substrate processing apparatus 1, the pod 3 is transferred to the mounting table 9. Then, an end surface of the pod 3 placed on the mounting table 9 is pressed against an opening edge of the wafer loading/unloading port 7 of the front wall 5 of the sub-housing 4. The opening/closing structure 11 detaches the lid of the pod 3, and the wafer entrance of the pod 3 is opened.

When the pod 3 is opened by the pod opener 8, the sensor rods 27a and 27b of the transfer robot 13 are moved to the protruded positions (in a direction toward the pod 3) by the forward/backward drivers 28a and 28b. Then, the sensor rods 27a and 27b are moved up and down at a constant speed by the Z-axis direction driver 23. By mapping the wafers 6 by using the fiber sensors 29a and 29b, it is possible to detect the wafers 6 in the pod 3 in a sequential order.

After the mapping operation is completed, the sensor rods 27a and 27b are returned to the retracted positions. Then, in accordance with the wafer transfer position information corrected based on the amount of correction obtained by the teaching process, the operations in which the wafer mounting plate 14 is advanced, elevated and retreated, the Y-axis rotation driver 24 is pivoted, and the wafer mounting plate 14 is advanced, lowered and retreated are performed sequentially and repeatedly. Thereby, the wafers 6 are picked up from an inside of the pod 3 through the wafer loading/unloading port 7, and are loaded (charged) into the boat 15 from a direction facing the support column 15b.

After the wafers 6 are loaded (charged) into the boat 15, a lower end of the process furnace 16 closed by the furnace opening shutter is opened by the furnace opening shutter. Subsequently, as the seal cap 19 is elevated by the boat elevator 18 (that is, “boat up”), the boat 15 accommodating the wafers 6 is loaded (inserted) into the process furnace 16 from the transfer chamber 12.

### Film Forming Step

After the boat 15 is loaded, the heat treatment process is performed on the wafers 6 in the process chamber 17 inside the process furnace 16.

### Substrate Unloading Step

Subsequently, the boat 15 accommodating the wafers 6 on which the heat treatment process has been performed is unloaded (“boat unloading”) from the process chamber 17 to the transfer chamber 12. Then, a cooling operation is performed on the boat 15 accommodating the wafers 6 on which the heat treatment process has been performed.

After the cooling operation is completed, the sensor rods 27a and 27b of the transfer robot 13 are moved to the protruded positions by the forward/backward drivers 28a and 28b. Then, the sensor rods 27a and 27b are moved up and down by the Z-axis direction driver 23, and the mapping operation is performed on the wafers 6 by using the fiber sensors 29a and 29b. When the mapping operation is completed, the sensor rods 27a and 27b return to the storage positions, and the wafers 6 are transferred by the wafer mounting plates 14 in accordance with the wafer transfer position information, and are transferred into the pod 3. Thereafter, the pod 3 is unloaded out of the housing 2.

According to the present embodiments, it is possible to obtain one or more effects described below.

According to the present embodiments, when the boat 15 is reinstalled after being removed for performing a work such as a maintenance work, for example, it is possible to automatically detect the tilt of the reinstalled boat 15 by the fiber sensors 29a and 29b used for the mapping operation.

Therefore, it is possible to eliminate the need for the operator to manually measure the tilt of the boat 15. As a result, it is possible to shorten a work time and to reduce a workload. In addition, since the fiber sensors 29a and 29b serve as both the mapping sensor and a sensor capable of detecting the tilt of the boat 15, it is possible to omit a separate sensor capable of detecting the tilt of the boat 15. As a result, it is possible to reduce a manufacturing cost.

In addition, since the deviation of the center position of the boat 15 in the height direction can be calculated based on the timing when the optical path formed between the fiber sensors 29a and 29b is blocked by an outer periphery of the support columns 15a to 15c or the optical path is unblocked, it is possible to simplify a processing related thereto, and it is also possible to shorten a processing time. In addition, since the transfer robot 13 and the rotator 21 can operate automatically and perform the tilt detection process based on the tilt detection program (which is set in advance), it is possible to eliminate the need for the operator to manually operate the transfer robot 13 and the rotator 21. As a result, it is possible to reduce labor.

For example, when the tilt of the boat 15 exceeds the reference degree, the alarm is issued, and the process of transferring the wafer 6 is not performed. Therefore, since a work such as a work of reinstalling the boat 15 can be performed before the teaching process is performed, as compared with a case where the detected tilt makes it impossible to perform the process of transferring the wafer 6 during the teaching process, it is possible to eliminate the need to interrupt (or stop) and re-execute the teaching process. As a result, it is possible to reduce a time lost in the maintenance work.

In addition, by calculating the tilt of the boat 15, an amount of eccentricity of the central axis of the boat 15 can also be determined. As a result, it is possible to determine a risk of contact with other components due to the rotation of the boat 15, and it is also possible to perform an evaluation that takes such a risk into account to some extent.

In addition, by the tilt detection process and the teaching process, it is possible to prevent the wafer 6 and the wafer mounting plate 14 from coming into contact with the support columns 15a to 15c and the like. As a result, it is possible to prevent an occurrence of the damage and a generation of particles.

For example, according to the present embodiments, the deviation in the X-axis direction and the Y-axis direction is calculated at each of the first height and the second height. However, the deviation calculated at three or more different heights may be fitted as a function in the direction of the rotation axis of the boat 15, and the deviation amount r, the deviation angle φ₀ and the direction angle θ₀ may be calculated based on the fitting results.

For example, according to the present embodiments, the deviation of the center of the boat 15 relative to the reference position is calculated based on the times when the each of the support columns 15a to 15c starts crossing the laser beam 39 and the times when the each of the support columns 15a to 15c finishes crossing the laser beam 39, that is, based on the timings. Alternatively, the deviation of the center of the boat 15 relative to the reference position may be calculated based on an angle relative to the reference angle when each of the support columns 15a to 15c crosses the laser beam 39.

For example, according to the present embodiments, the boat 15 is constantly rotated at a constant speed when performing the R-axis scanning. However, the boat 15 may not be constantly rotated at the constant speed when performing the R-axis scanning. For example, it is sufficient that the boat 15 is rotated at the constant speed from the time when the support column 15a starts blocking the laser beam until the support column 15b finishes blocking the laser beam, or from the time when the support column 15b starts blocking the laser beam until the support column 15c finishes blocking the laser beam. For example, the rotation of the boat 15 may be decelerated while the support column 15a blocks the laser beam, or the rotation speed of the boat 15 may be varied after the support column 15c finishes blocking the laser beam. By maintaining the rotation speed of the boat 15 constant while the two support columns cross (pass through) the laser beam, it is possible to accurately detect the time when each of the two support columns starts blocking the laser beam and the time when each of the two support columns finishes blocking the laser beam.

For example, according to the present embodiments, a shape of each of the support columns is a round rod with the outer periphery cut by a plane perpendicular to the radius when viewed from the center of the boat. However, the present embodiments are not limited thereto. As can be seen from FIG. 8, it is sufficient that the edge on a side surface of the support column always causes contact with the laser beam at an angle α, and a shape of a surface other than the edge (that is, a surface that is not in contact with the laser beam) may be set appropriately. In other words, the support column may be a triangular column or a rectangular column. To ensure such contact at the edge at the angle α, it is preferable that an angle β of an optical axis contact position measured from the Y-axis is set to be equal to or less than the angle α. In other words, Y_{obj} is increased such that an angle (2β) between a start and an end of the laser beam blocked by the support column is equal to or less than 2α.

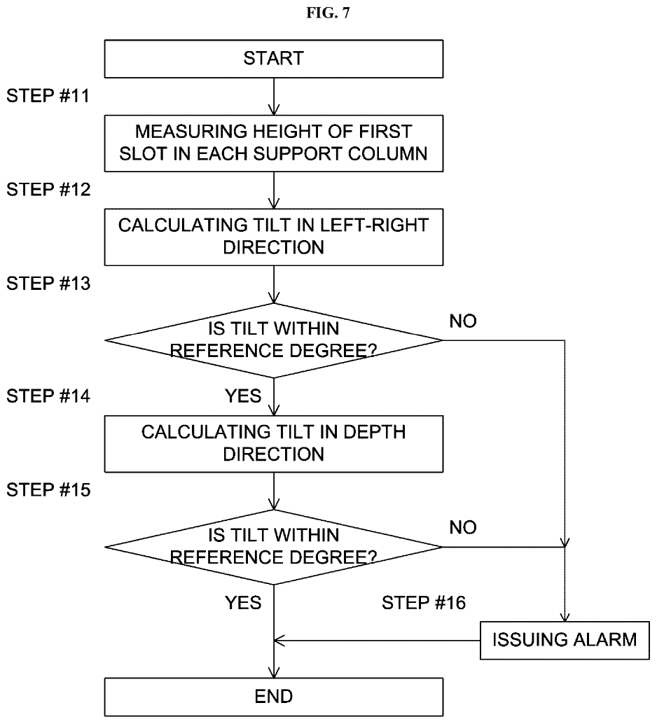

According to the present embodiments, the tilt of the boat 15 is calculated based on the difference between the center position and the height of the boat 15 at the first height and the second height. However, a method of obtaining the tilt of the boat 15 is not limited thereto. Hereinafter, a modified example of the tilt detection process according to the present embodiments will be described with reference to a flow chart in FIG. 7.

### STEP #11

The height of the first slot of each of the support columns 15a to 15c is measured. Specifically, the controller 31 controls the rotator 21 to rotate the boat 15 such that a target support column is located closest to the Y-axis of the transfer robot 13. Further, the controller 31 drives the Z-axis direction driver 23, the Y-axis rotation driver 24, the X-axis direction driver 25, the V-axis direction driver 26 and the forward/backward drivers 28a and 28b of the transfer robot 13 such that the first slot (lowermost slot for the wafer 6) of the support column 15a is located on the optical path of the laser beam 39.

Subsequently, the controller 31 controls the Z-axis direction driver 23 such that the fiber sensors 29a and 29b are moved slightly up and down near the known height of the first slot. Then, the controller 31 detects a position at which a change occurs such that an amount of light (laser beam) received by the fiber sensors 29a and 29b decreases when the fiber sensors 29a and 29b are lowered. In other words, the fiber sensors 29a and 29b detect a boundary between a state (crossing state) where the optical path of the laser beam 39 crossing the slot and a state (blocking state) where the optical path of the laser beam 39 is blocked by the support columns 15a to 15c. The boundary is determined using a threshold value midway between a maximum amount of the light received (a typical value in the crossing state) and a minimum amount of the light received (a typical value in the blocking state). In other words, the height of the optical path when the amount of the light received reaches the threshold value is determined to be a height of a lower surface of the first slot (that is, the substrate supporting surface).

The controller 31 stores the height of the lower surface of the first slot obtained for each support column in the memory 34.

### STEP #12

After the height from the reference height to the first slot for each of the support columns 15a to 15c is measured, in a state where the boat 15 is oriented toward a direction in which the wafer 6 is transferable, the controller 31 calculates a difference in a left-right direction when looking at the rotation axis of the boat 15 from a pivot axis of the transfer robot 13, that is, a height difference in the height of the first slots of the support columns 15a and 15c, and calculates a tilt of the boat 15 in the left-right direction based on the height difference.

### STEP #13

The controller 31 determines whether the tilt of the boat 15 in the left-right direction calculated in the STEP #12 is within a reference degree. The reference degree is substantially the same as in the embodiments mentioned above. When the tilt in the left-right direction is within the reference degree, the wafer 6 and the wafer mounting plate 14 do not come into contact with the support columns 15a to 15c of the boat 15 when the wafer 6 is transferred.

### STEP #14

When it is determined that the tilt of the boat 15 in the left-right direction is within the reference degree, the controller 31 then calculates a tilt of the boat 15 in a depth direction. The term “depth direction” may refer to a front-rear direction when looking at the rotation axis of the boat 15 from the pivot axis of the transfer robot 13, in a state where the boat 15 is oriented toward the direction in which the wafer 6 can be transferred. After calculating a difference between an average height of the first slot of the support column 15a and the first slot of the support column 15c and the height of the first slot of the support column 15b, the tilt of the boat 15 in the depth direction is calculated based on the difference calculated as described above.

### STEP #15

The controller 31 determines whether the tilt of the boat 15 in the depth direction calculated in the STEP #14 is within the reference degree. When it is determined that the tilt in the depth direction is within the reference degree, it is determined that the tilt in the depth direction does not interfere with the operation of transferring the wafer 6, and the tilt detection process is terminated. After the tilt detection process is terminated, the wafers 6 are transferred to the boat 15, and the substrate processing mentioned above is performed.

### STEP #16

When it is determined, in the STEP #13, that the tilt of the boat 15 in the left-right direction exceeds the reference degree, or when it is determined, in the STEP #15, that the tilt of the boat 15 in the depth direction exceeds the reference degree, the controller 31 issues an alarm and terminates the tilt detection process. The content of the alarm is substantially the same as in the embodiments mentioned above. For example, the alarm may also serve to identify whether the tilt in the left-right direction or the tilt in the depth direction exceeds the reference degree. Even in such a modified example, it is possible to obtain substantially the same effects as in the embodiments mentioned above. In addition, since the tilt of the boat 15 can be determined from detection results of the fiber sensors 29a and 29b and such calculations, it is possible to determine the tilt of the boat 15 easily in a short time.

The technique of the present disclosure is not limited to the embodiments and the modified example mentioned above, and may further include various other modified examples. For example, the embodiments and the modified example mentioned above are described in detail to clearly explain the technique of the present disclosure. That is, the technique of the present disclosure is not limited to those including the entirety of configurations described above.

For example, the controller 31 mentioned above may be implemented by two pieces of hardware, that is, a main controller configured to mainly control the process and a subsidiary controller configured to control a transfer system including components such as the transfer robot 13. In addition, Furthermore, the subsidiary controller may control each component of the transfer robot 13 via a PLC (Programmable Logic Controller), and the entirety of the detection process of detecting the positional deviation in the examples mentioned above may be performed by the PLC. Thereby, since preparation for teaching can be performed without accessing the main controller, it is possible to reduce a security risk.

For example, the embodiments and the modified example mentioned above are described by way of an example in which the batch type substrate processing apparatus capable of simultaneously processing a plurality of substrates is used form a film. However, the technique of the present disclosure is not limited thereto. For example, the technique of the present disclosure may be preferably applied when a single wafer type substrate processing apparatus capable of processing one or several substrates at a time is used to form the film. For example, the embodiments and the modified example mentioned above are described by way of an example in which the substrate processing apparatus 1 including a hot wall type process furnace is used to form the film. However, the technique of the present disclosure is not limited thereto. For example, the technique of the present disclosure may be preferably applied when a substrate processing apparatus including a cold wall type process furnace is used to form the film.

As described above, according to some embodiments of the present disclosure, it is possible to detect the tilt of the substrate retainer.

What is claimed is:

1. A substrate processing apparatus comprising:
a rotator configured to rotatably support a substrate retainer provided with a plurality of support columns;
a sensor attached to a transfer robot configured to transfer a substrate to the substrate retainer such that a distance between the sensor and the substrate retainer and a relative height of the sensor with respect to the substrate retainer are variable, and configured to be capable of detecting the plurality of support columns within an optical path thereof; and
a controller configured to be capable of:
(a) causing the rotator to rotate the substrate retainer such that the plurality of support columns intersect with the optical path;
(b) calculating center positions of the substrate retainer from detection results of the sensor at a plurality of heights; and
(c) determining whether a tilt of the substrate retainer is within a reference degree based on a difference in the center positions in a height direction.

2. The substrate processing apparatus of claim 1, wherein the optical path is set to be substantially perpendicular to a longitudinal direction of the substrate retainer, and the controller is further configured to be capable of calculating the center positions of the substrate retainer in (b) based on an angle or a timing at which the optical path is blocked by the plurality of support columns.

3. The substrate processing apparatus of claim 1, wherein two edges where the plurality of support columns initially and lastly come into contact with the optical path as the substrate retainer is rotated are provided on side surfaces of the plurality of support columns at each of the plurality of heights.

4. The substrate processing apparatus of claim 1, further comprising:
a process chamber in which a heat treatment process is performed on the substrate supported by the plurality of support columns of the substrate retainer;
a transfer chamber located adjacent to the process chamber and configured to be capable of accommodating the substrate retainer; and
the transfer robot configured to load the substrate into and unload the substrate out of the substrate retainer in the transfer chamber.

5. The substrate processing apparatus of claim 2, wherein the sensor further serves as a mapping sensor capable of detecting the substrate in the substrate retainer by blocking the optical path.

6. The substrate processing apparatus of claim 2, wherein the sensor is driven by a sensor driver such that the sensor is capable of being stopped with a predetermined positioning accuracy at only two positions, and
the two positions are constituted by: an advanced position where the sensor is located near a center of the substrate retainer; and a retracted position where the sensor is located away from the center of the substrate retainer.

7. The substrate processing apparatus of claim 2, wherein the sensor is stationary while detecting a blocking of the optical path.

8. The substrate processing apparatus of claim 6, wherein the controller is further configured to control the sensor driver to move the sensor to the retracted position when the sensor in the advanced position mechanically interferes with one of the plurality of support columns.

9. The substrate processing apparatus of claim 1, wherein, in a state where the substrate retainer is oriented toward a direction in which the substrate is transferable, the tilt of the substrate retainer is calculated as an angle of the tilt of the substrate retainer in a front-rear direction and a left-right direction when looking at a rotation axis of the substrate retainer from a pivot axis of the transfer robot, or as an amount of a positional deviation at an uppermost substrate supporting position.

10. The substrate processing apparatus of claim 1, wherein the controller is further configured to be capable of determining whether the tilt of the substrate retainer is within a range in which the substrate is transferable by the transfer robot before performing a teaching process.

11. The substrate processing apparatus of claim 1, wherein the controller is further configured to fit, as a function in a direction of a rotation axis of the substrate retainer, a deviation calculated at each of different positions in the direction of the rotation axis to finally calculate the deviation.

12. The substrate processing apparatus of claim 2, wherein the controller is further configured to control the substrate retainer to rotate at a constant speed while at least one among the plurality of support columns blocks the optical path.

13. The substrate processing apparatus of claim 1, wherein the controller is further configured to calculate a deviation of the center positions in the height direction using either one of a rotation angle of the substrate retainer or a timing when the optical path is blocked by an outer periphery of the plurality of support columns or when the optical path is unblocked.

14. The substrate processing apparatus of claim 1, wherein the controller is further configured to numerically calculate a solution to three or more nonlinear simultaneous equations comprising, as unknowns, a positional deviation of a center of the substrate retainer relative to a rotation axis of the substrate retainer and a deviation of an angle of the substrate retainer relative to a reference angle.

15. A substrate processing apparatus comprising:
a sensor attached to a transfer robot configured to transfer a substrate to a substrate retainer, and configured to be capable of detecting a height of a substrate supporting surface of each of support columns of the substrate retainer; and
a controller configured to be capable of determining whether a tilt of the substrate retainer is within a reference degree based on a difference in heights detected by the sensor.

16. A method of detecting a tilt of a substrate retainer, comprising:
(a) rotating the substrate retainer provided with a plurality of support columns by using a rotator configured to rotatably support the substrate retainer such that the plurality of support columns intersect with an optical path of a sensor, wherein the sensor is attached to a transfer robot configured to transfer a substrate to the substrate retainer such that a distance between the sensor and the substrate retainer and a relative height of the sensor with respect to the substrate retainer are variable;
(b) calculating center positions of the substrate retainer from detection results of the sensor at a plurality of heights; and
(c) determining whether a tilt of the substrate retainer is within a reference degree based on a difference in the center positions in a height direction.

17. A substrate processing method comprising:
the method of claim 16;
(d) transferring the substrate from a container to the substrate retainer whose tilt is determined to be within the reference degree; and
(e) loading the substrate retainer into a process chamber and processing the substrate.

18. A method of manufacturing a semiconductor device, comprising the method of claim 17.

19. A non-transitory computer-readable recording medium storing a program that causes a substrate processing apparatus, by a computer, to perform a process comprising the method of claim 16.
